(19) United States
(12) Patent Application Publication
(10) Pub. No.: US 2025/0151637 A1
(43) Pub. Date: May 8, 2025

(54) METHODS AND APPARATUSES FOR DIRECT D-STATE EXCITATION SCHEME FOR INDIVIDUAL PHOTON EXTRACTION

(71) Applicant: IonQ, Inc., College Park, MD (US)

(72) Inventors: James David SIVERNS, Bothell, WA (US); Ryan Steven Bowler, Kirkland, WA (US)

(21) Appl. No.: 18/938,088

(22) Filed: Nov. 5, 2024

Related U.S. Application Data
(60) Provisional application No. 63/597,206, filed on Nov. 8, 2023.

(51) Int. Cl. H10N 79/00; H10N 60/85; H10N 70/00

(52) U.S. Cl. CPC H10N 79/00; H10N 60/855; H10N 70/821

(57) ABSTRACT

Aspects of the present disclosure may include methods and systems for applying a first light to transition at least one trapped ion of a first quantum processing unit from a ground state to an intermediate state via a narrow quadrupole transition, applying a second light to transition the at least one trapped ion from the intermediate state to an excited state, and directing at least one photon, emitted from the trapped ion relaxing from the excited state back to the ground state, toward a second quantum processing unit to entangle the first quantum processing unit and the second quantum processing unit.

### CROSS-REFERENCE TO RELATED APPLICATIONS

The current application claims priority to U.S. Provisional Application No. 63/597,206 filed Nov. 8, 2024 and entitled “METHODS AND APPARATUSES FOR DIRECT D-STATE EXCITATION SCHEME FOR INDIVIDUAL PHOTON EXTRACTION,” the contents of which are hereby incorporated by reference in their entireties.

### BACKGROUND

In a quantum information processing (QIP) system, the entanglement of trapped ions in an ion chain is used for performing logic and/or quantum computation. The quantum states of the trapped ions represent the computational states for quantum logic. Scaling may be achieved with separate quantum processing units (QPUs) linked together into larger systems capable of performing more complex calculations. A photonic link may be used to achieve this through individual photon extraction in separate trap systems. This photonic link may require the creation of entanglement between an interconnect ion state and a photon in each QPU. The fidelity and rate of this ion-photon entanglement may be used as the metrics for the performance for a photonic link between QPUs. Therefore, it may be important to create this entanglement quickly and with high fidelity.

### SUMMARY

The following presents a simplified summary of one or more aspects to provide a basic understanding of the disclosure. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

Aspects of the present disclosure may include methods and systems for applying a first light to transition for at least one trapped ion of a first quantum processing unit from a ground state to an intermediate state via a narrow quadrupole transition, applying a second light to transition the at least one trapped ion from the intermediate state to an excited state, and directing at least one photon, emitted from the trapped ion relaxing from the excited state back to the ground state, toward a second quantum processing unit to entangle the first quantum processing unit with a second quantum processing unit.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 illustrates a view of atomic ions in a linear crystal, or chain, in accordance with aspects of this disclosure.

FIG. 2 illustrates an example of a quantum information processing (QIP) system in accordance with aspects of this disclosure.

FIG. 3 illustrates an example of a computer device in accordance with aspects of this disclosure.

FIG. 4 illustrates examples of a scheme for photon-ion entanglement using a narrow quadrupole laser beam in accordance with aspects of this disclosure

FIG. 5 illustrates an example of a method for photon-ion entanglement using a narrow quadrupole laser beam according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form to avoid obscuring such concepts.

A conventional scheme for the ion-photon entanglement process based on group II alkali earth metals typically uses a multibeam preparation into a D_{3/2} state prior to the entanglement generation, where the rate can be limited by the multibeam preparation rate The multibeam preparation is then followed by a pulse of excitation light that transfers population from the D_{3/2} to the P_{1/2} level from which decay produces a single photon.

Another scheme that overcomes rate limitations utilizes a pulsed laser to directly drive the S_{1/2} to P_{1/2} transition without the need for D-state preparation. However, the use of this pulsed laser comes at the expense of destroying any qubit states stored in the same element of ion nearby unless highly focused individual addressing beams are used. It can also increase the risk of exciting the state multiple times in a single attempt. This configuration can make integration of interconnect and computation laser beams impractical without significant disruption of QPU operation.

An aspect of the present disclosure includes performing a direct quadrupole transition that replaces the multibeam D_{3/2} state preparation step of the individual photon extraction process described above. This direct D-state state preparation scheme means that the main limit to the speed at which this step can be performed is the power and stability in the single laser resonant with this transition. The transition, being a narrow quadrupole, also allows for very precise state selectivity for the preparation step which will not disturb nearby qubits stored in neighboring ions in the S-state if multi-species or multi-isotope architectures are used in the QPU.

In some aspects, the direct state preparation step of the current scheme is then followed by a pulse of excitation light from the D_{3/2} to P_{1/2} level from which decay produces a single photon.

In some aspects of the present disclosure, elements in the group II alkali earth metals may be utilized for the entanglement procedures described herein.

The scheme described in the current application utilizes a narrow beam for the direct quadrupole transition. As a result, there is a reduction in the undesirable optical cross talk (commonly associated with larger linewidths lasers) present in other schemes. Due to the narrowness of the beam, there are less disturbances to neighboring trapped ions and/or less unintended state transitions in the QPU

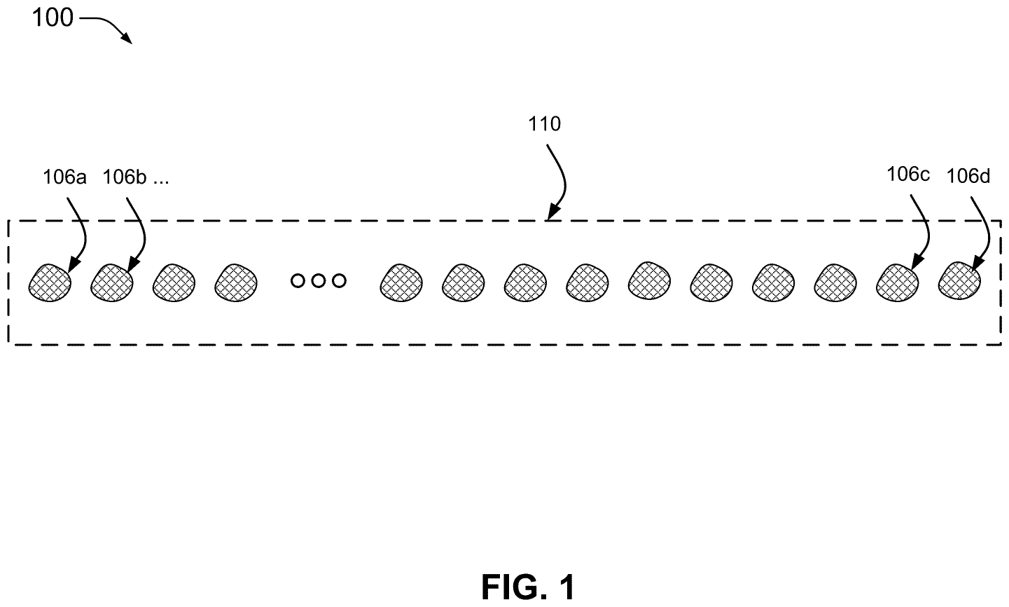

Example QIP systems that may implement aspects of the present disclosure are shown in FIGS. 1-3.

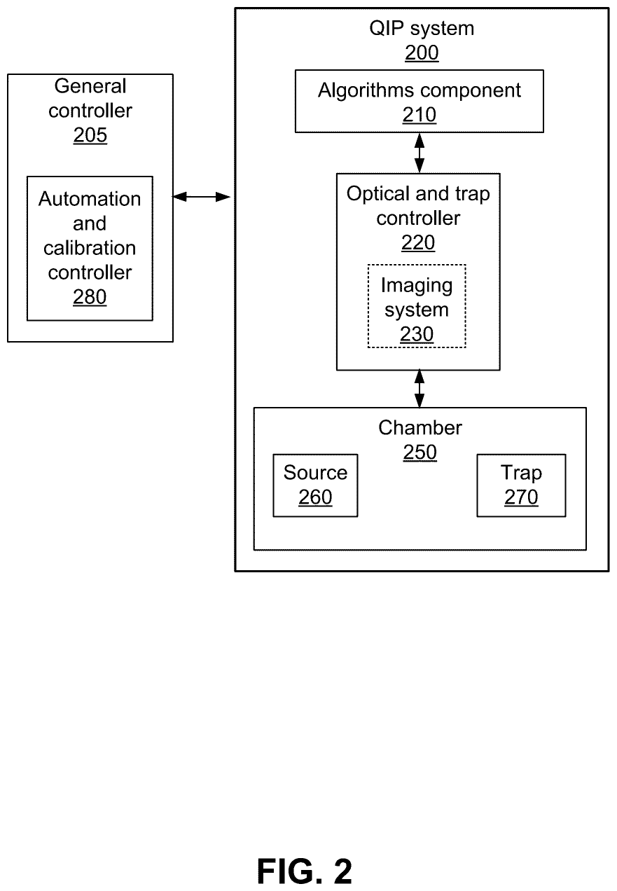

FIG. 1 shown below illustrates a diagram 100 with multiple atomic ions 106 (e.g., atomic ions 106a, 106b, . . . , 106c, and 106d) trapped in a linear crystal or chain 110 using a trap (the trap can be inside a vacuum chamber as shown in FIG. 2). The trap may be referred to as an ion trap. The ion trap shown may be built or fabricated on a semiconductor substrate, a dielectric substrate, or a glass die or wafer (also referred to as a glass substrate). The atomic ions 106 may be provided to the trap as atomic species for ionization and confinement into the chain 110.

In the example shown in FIG. 1, the trap includes electrodes for trapping or confining multiple atomic ions into the chain 110 that are laser-cooled to be nearly at rest. The number of atomic ions (N) trapped can be configurable and more or fewer atomic ions may be trapped. The atomic ions can be Ytterbium ions (e.g., 171Yb+ ions), for example. The atomic ions are illuminated with laser (optical) radiation tuned to a resonance in 171Yb+ and the fluorescence of the atomic ions is imaged onto a camera or some other type of detection device. In this example, atomic ions may be separated by about 5 microns (μm) from each other, although the separation may be smaller or larger than 5 μm. The separation of the atomic ions is determined by a balance between the external confinement force and Coulomb repulsion and does not need to be uniform. Moreover, in addition to atomic ytterbium ions, neutral atoms, Rydberg atoms, different atomic ions or different species of atomic ions may also be used (such as one or more isotopes of barium, for example). The trap may be a linear RF Paul trap, but other types of confinement may also be used, including optical confinements. Thus, a confinement device may be based on different techniques and may hold ions, neutral atoms, or Rydberg atoms, for example, with an ion trap being one example of such a confinement device. The ion trap may be a surface trap, for example.

FIG. 2 shown below is a block diagram that illustrates an example of a QIP system 200 in accordance with various aspects of this disclosure.

The QIP system 200 may also be referred to as a quantum computing system, a quantum computer, a computer device, a trapped ion system, or the like. The QIP system 200 may be part of a hybrid computing system in which the QIP system 200 is used to perform quantum computations and operations and the hybrid computing system also includes a classical computer to perform classical computations and operations.

Shown in FIG. 2 is a general controller 205 configured to perform various control operations of the QIP system 200. Instructions for the control operations may be stored in memory (not shown) in the general controller 205 and may be updated over time through a communications interface (not shown). Although the general controller 205 is shown separate from the QIP system 200, the general controller 205 may be integrated with or be part of the QIP system 200. The general controller 205 may include an automation and calibration controller 280 configured to perform various calibration, testing, and automation operations associated with the QIP system 200.

The QIP system 200 may include an algorithms component 210 that may operate with other parts of the QIP system 200 to perform quantum algorithms or quantum operations, including a stack or sequence of combinations of single qubit operations and/or multi-qubit operations (e.g., two-qubit operations) as well as extended quantum computations. As such, the algorithms component 210 may provide instructions to various components of the QIP system 200 (e.g., to the optical and trap controller 220) to enable the implementation of the quantum algorithms or quantum operations. The algorithms component 210 may receive information resulting from the implementation of the quantum algorithms or quantum operations and may process the information and/or transfer the information to another component of the QIP system 200 or to another device for further processing.

The QIP system 200 may include an optical and trap controller 220 that controls various aspects of a trap 270 in a chamber 250, including the generation of signals to control the trap 270, and controls the operation of lasers and optical systems that provide optical beams that interact with the atoms or ions in the trap. When used to confine or trap ions, the trap 270 may be referred to as an ion trap. The trap 270, however, may also be used to trap neutral atoms, Rydberg atoms, different atomic ions or different species of atomic ions. The lasers and optical systems can be at least partially located in the optical and trap controller 220 and/or in the chamber 250. For example, optical systems within the chamber 250 may refer to optical components or optical assemblies.

The QIP system 200 may include an imaging system 230. The imaging system 230 may include a high-resolution imager (e.g., CCD camera) or other type of detection device (e.g., photomultiplier tube or PMT) for monitoring the atomic ions while they are being provided to the trap 270 and/or after they have been provided to the trap 270. In an aspect, the imaging system 230 can be implemented separate from the optical and trap controller 220, however, the use of fluorescence to detect, identify, and label atomic ions using image processing algorithms may need to be coordinated with the optical and trap controller 220. A related aspect to an imaging system collects the individual photon used for a photonic link.

In addition to the components described above, the QIP system 200 can include a source 260 that provides atomic species (e.g., a plume or flux of neutral atoms) to the chamber 250 having the trap 270. When atomic ions are the basis of the quantum operations, that trap 270 confines the atomic species once ionized (e.g., photoionized). The trap 270 may be part of a processor or processing portion of the QIP system 200. That is, the trap 270 may be considered at the core of the processing operations of the QIP system 200 since it holds the atomic-based qubits that are used to perform the quantum operations or simulations. At least a portion of the source 260 may be implemented separate from the chamber 250.

It is to be understood that the various components of the QIP system 200 described in FIG. 2 are described at a high-level for ease of understanding. Such components may include one or more sub-components, the details of which may be provided below as needed to better understand certain aspects of this disclosure.

Aspects of this disclosure may be implemented at least partially using the general controller 205, the automation and calibration controller 280, the optical and trap controller 220, and/or the imaging system 230.

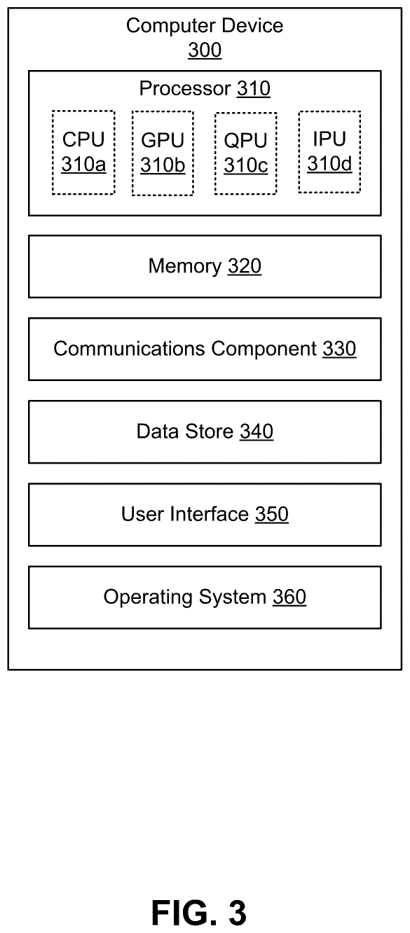

Referring now to FIG. 3 shown below, illustrated is an example of a computer system or device 300 in accordance with aspects of the disclosure. The computer device 300 can represent a single computing device, multiple computing devices, or a distributed computing system, for example. The computer device 300 may be configured as a quantum computer (e.g., a QIP system), a classical computer, or to perform a combination of quantum and classical computing functions, sometimes referred to as hybrid functions or operations. For example, the computer device 300 may be used to process information using quantum algorithms, classical computer data processing operations, or a combination of both. In some instances, results from one set of operations (e.g., quantum algorithms) are shared with another set of operations (e.g., classical computer data processing). A generic example of the computer device 300 implemented as a QIP system capable of performing quantum computations and simulations is, for example, the QIP system 200 shown in FIG. 2.

The computer device 300 may include a processor 310 for carrying out processing functions associated with one or more of the features described herein. The processor 310 may include a single or multiple set of processors or multi-core processors. Moreover, the processor 310 may be implemented as an integrated processing system and/or a distributed processing system. The processor 310 may include one or more central processing units (CPUs) 310a, one or more graphics processing units (GPUs) 310b, one or more quantum processing units (QPUs) 310c, one or more intelligence processing units (IPUs) 310d (e.g., artificial intelligence or AI processors), or a combination of some or all those types of processors. In one aspect, the processor 310 may refer to a general processor of the computer device 300, which may also include additional processors 310 to perform more specific functions (e.g., including functions to control the operation of the computer device 300).

The computer device 300 may include a memory 320 for storing instructions executable by the processor 310 to carry out operations. The memory 320 may also store data for processing by the processor 310 and/or data resulting from processing by the processor 310. In an implementation, for example, the memory 320 may correspond to a computer-readable storage medium that stores code or instructions to perform one or more functions or operations. Just like the processor 310, the memory 320 may refer to a general memory of the computer device 300, which may also include additional memories 320 to store instructions and/or data for more specific functions. The memory 320 may be a non-transitory computer readable medium.

It is to be understood that the processor 310 and the memory 320 may be used in connection with different operations including but not limited to computations, calculations, simulations, controls, calibrations, system management, and other operations of the computer device 300, including any methods or processes described herein.

Further, the computer device 300 may include a communications component 330 that provides for establishing and maintaining communications with one or more parties utilizing hardware, software, and services. The communications component 330 may also be used to carry communications between components on the computer device 300, as well as between the computer device 300 and external devices, such as devices located across a communications network and/or devices serially or locally connected to computer device 300. For example, the communications component 330 may include one or more buses, and may further include transmit chain components and receive chain components associated with a transmitter and receiver, respectively, operable for interfacing with external devices. The communications component 330 may be used to receive updated information for the operation or functionality of the computer device 300. This communications component may also include photonic links between QPUs in different computer devices.

Additionally, the computer device 300 may include a data store 340, which can be any suitable combination of hardware and/or software, which provides for mass storage of information, databases, and programs employed in connection with the operation of the computer device 300 and/or any methods or processes described herein. For example, the data store 340 may be a data repository for operating system 360 (e.g., classical OS, or quantum OS, or both). In one implementation, the data store 340 may include the memory 320. In an implementation, the processor 310 may execute the operating system 360 and/or applications or programs, and the memory 320 or the data store 340 may store them.

The computer device 300 may also include a user interface component 350 configured to receive inputs from a user of the computer device 300 and further configured to generate outputs for presentation to the user or to provide to a different system (directly or indirectly). The user interface component 350 may include one or more input devices, including but not limited to a keyboard, a number pad, a mouse, a touch-sensitive display, a digitizer, a navigation key, a function key, a microphone, a voice recognition component, any other mechanism capable of receiving an input from a user, or any combination thereof. Further, the user interface component 350 may include one or more output devices, including but not limited to a display, a speaker, a haptic feedback mechanism, a printer, any other mechanism capable of presenting an output to a user, or any combination thereof. In an implementation, the user interface component 350 may transmit and/or receive messages corresponding to the operation of the operating system 360. When the computer device 300 is implemented as part of a cloud-based infrastructure solution, the user interface component 350 may be used to allow a user of the cloud-based infrastructure solution to remotely interact with the computer device 300.

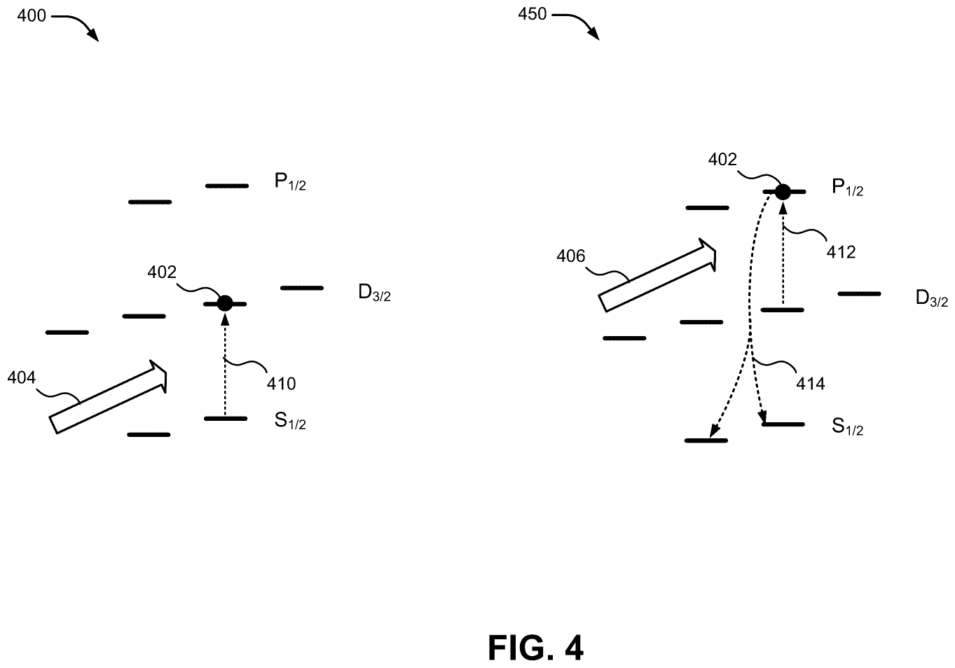

FIG. 4 illustrates a scheme of direct D-state state preparation according to aspects of the present disclosure. In an exemplary aspect, the scheme can be implemented by the QIP system 200 of FIG. 2 and/or the computer device 300 of FIG. 3. More particularly, the scheme can be implemented by the general controller 205 that can be configured to control optical and trap controller 220 to generate one or more lasers to perform the direct D-state state preparation of trapped ions in ion trap 270. For example, the optical and trap controller 220 can be coupled to and/or include an optical source(s) that is configured to generate lasers applied through a window of the chamber 250 and to ions in the ion trap 270 according to an exemplary aspect.

During a first step 400 (or first stage of the operation or scheme), a first light 404 having a narrow linewidth, such as a laser generated by the optical and trap controller 220, may be applied to a trapped ion 402 resting at the S_{1/2} ground state. In some aspects of the present disclosure, the first light 404 can be configured to drive a narrow quadrupole transition 410 of the trapped ion 402 from the S_{1/2} ground state to the D_{3/2} state. The wavelength of the first light 404 may be sufficiently narrow to prevent the transition from the S_{1/2} ground state to states other than the D_{3/2} state.

During a second step 450 (or second stage of the operation or scheme), a second light 406, such as a laser generated by the optical and trap controller 220, may be applied to the trapped ion 402 in the D_{3/2} state. The second light 406 may be an excitation laser configured to cause an excitation 412 of the trapped ion 402 from the D_{3/2} state to the P_{1/2} state. According to the exemplary aspect, the second light 406 is applied to the trapped ion 402 to excite the trapped ion 402 to from the D_{3/2} state to the P_{1/2} state.

In some aspects of the present disclosure, after transitioning to the P_{1/2} state, the trapped ion 402 may relax 414 back to the S_{1/2} state. Specifically, the relaxation in energetic state may cause the trapped ion 402 to emit photons. The photons emitted may be used to entangle one or more quantum processing units.

Aspects of the present disclosure may include reducing optical cross-talk during ion-photon entanglement compared to other schemes. This may be caused by the narrow quadrupole transition that reduces optical cross-talk of trapped ions. As a result, there is a reduction in the undesirable optical cross talk (commonly associated with larger linewidths lasers) present in other schemes.

In some aspects of the present disclosure, the trapped ion 402 may be part of group II alkali earth metal. Other elements may also be suitable for the trapped ion 402.

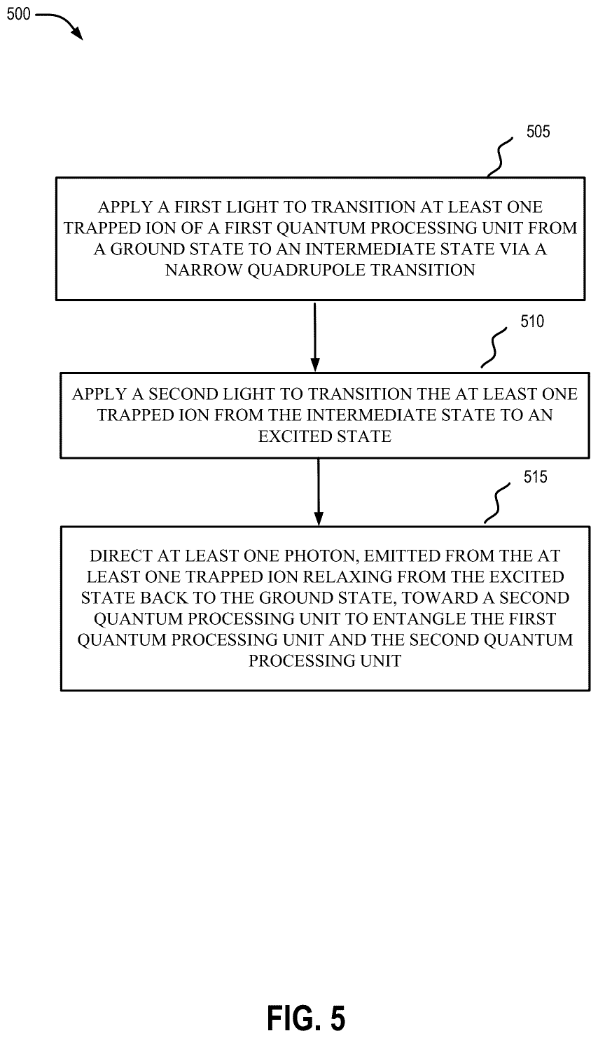

FIG. 5 illustrates an example of a method 500 of implementing photon-ion entanglement via direct D-state transition according aspects of the present disclosure. In general, it is noted that the method 500 may be performed by the general controller 205, the algorithms component 210, the optical and trap controller 220, the imaging system 230, the processor 310, the memory 320, and/or one or more subcomponents of the QIP system 200 or the computer device 300 according to various exemplary aspects as described above.

Initially, at 505, the method 500 may apply a first light to transition at least one trapped ion of a first quantum processing unit from a ground state to an intermediate state via a narrow quadrupole transition. For example, the general controller 205, the automation and calibration controller 280, the algorithms component 210, the optical and trap controller 220, the imaging system 230, the processor 310, the memory 320, and/or one or more subcomponents of the QIP system 200 or the computer device 300 may be configured to, and/or provide means for applying a first light to transition at least one trapped ion from a ground state to an intermediate state via a narrow quadrupole transition.

At 510, the method 500 may apply a second light to transition at least one trapped ion from the intermediate state to an excited state. For example, the general controller 205, the automation and calibration controller 280, the algorithms component 210, the optical and trap controller 220, the imaging system 230, the processor 310, the memory 320, and/or one or more subcomponents of the QIP system 200 or the computer device 300 may be configured to, and/or provide means for applying a second light to transition the at least one trapped ion from the intermediate state to an excited state.

At 515, the method 500 may direct at least one photon, emitted from the trapped ion relaxing from the excited state back to the ground state, toward a second quantum processing unit to entangle the first quantum processing unit and the second quantum processing unit. For example, the general controller 205, the automation and calibration controller 280, the algorithms component 210, the optical and trap controller 220, the imaging system 230, the processor 310, the memory 320, and/or one or more subcomponents of the QIP system 200 or the computer device 300 may be configured to, and/or provide means for directing at least one photon, emitted from the trapped ion relaxing from the excited state back to the ground state, toward a second quantum processing unit to entangle the first quantum processing unit and the second quantum processing unit.

Aspects of the present disclosure may include methods and systems for applying a first light to transition at least one trapped ion of a first quantum processing unit from a ground state to an intermediate state via a narrow quadrupole transition, applying a second light to transition the at least one trapped ion from the intermediate state to an excited state, and directing at least one photon, emitted from the trapped ion relaxing from the excited state back to the ground state, toward a second quantum processing unit to entangle the first quantum processing unit and the second quantum processing unit.

Aspects of the present disclosure include the method and/or system above, wherein at least one trapped ion is from group II alkali earth metals.

Aspects of the present disclosure include any of the method and/or system above, wherein applying the first light may, for example, comprise applying the first light through an ultra-low expansion cavity.

Aspects of the present disclosure include any of the method and/or system above, wherein the first light is a narrow-linewidth light.

The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method of implementing photon-ion entanglement, comprising:
applying a first light to transition at least one trapped ion of a first quantum processing unit from a ground state to an intermediate state via a narrow quadrupole transition;
applying a second light to transition the at least one trapped ion from the intermediate state to an excited state; and
directing at least one photon, emitted from the at least one trapped ion relaxing from the excited state back to the ground state, toward a second quantum processing unit to entangle the first quantum processing unit and the second quantum processing unit.

2. The method of claim 1, wherein the at least one trapped ion is from group II alkali earth metals.

3. The method of claim 1, wherein applying the first light comprises applying the first light through an ultra-low expansion cavity.

4. The method of claim 1, wherein the first light is a narrow-linewidth light.

5. A quantum information processing (QIP) system, comprising:
a plurality of light sources configured to:
apply a first light to transition at least one trapped ion of a first quantum processing unit from a ground state to an intermediate state via a narrow quadrupole transition, and
apply a second light to transition the at least one trapped ion from the intermediate state to an excited state; and
a controller configured to:
direct at least one photon, emitted from the at least one trapped ion relaxing from the excited state back to the ground state, toward a second quantum processing unit to entangle the first quantum processing unit and the second quantum processing unit.

6. The QIP system of claim 5, wherein the at least one trapped ion is from group II alkali earth metals.

7. The QIP system of claim 5, further comprises an ultra-low expansion cavity, wherein the first light is applied through the ultra-low expansion cavity.

8. The QIP system of claim 5, wherein the first light is a narrow-linewidth light.

9. A non-transitory computer readable medium having instructions that, when executed by one or more processors of a quantum information processing (QIP) system, cause the one or more processors to:
cause a plurality of light sources to apply a first light to transition at least one trapped ion of a first quantum processing unit from a ground state to an intermediate state via a narrow quadrupole transition;
cause the plurality of light sources to apply a second light to transition the at least one trapped ion from the intermediate state to an excited state; and
cause a controller to direct at least one photon, emitted from the at least one trapped ion relaxing from the excited state back to the ground state, toward a second quantum processing unit to entangle the first quantum processing unit and the second quantum processing unit.

10. The non-transitory computer readable medium of claim 9, wherein the at least one trapped ion is from group II alkali earth metals.

11. The non-transitory computer readable medium of claim 9, wherein the instructions for applying the first light comprises instructions for applying the first light through an ultra-low expansion cavity.

12. The non-transitory computer readable medium of claim 9, wherein the first light is a narrow-linewidth light.
